(19) United States
(12) Patent Application Publication
(10) Pub. No.: US 2025/0053094 A1
(43) Pub. Date: Feb. 13, 2025

(54) SHUTTER DEVICE, LITHOGRAPHY APPARATUS, AND ARTICLE MANUFACTURING METHOD

(71) Applicant: CANON KABUSHIKI KAISHA, Tokyo (JP)

(72) Inventors: KENTAROU USHIKU, Tochigi (JP); MIZUMA MURAKAMI, Tochigi (JP); MAHIRO SAITO, Tochigi (JP)

(21) Appl. No.: 18/791,608

(22) Filed: Aug. 1, 2024

(30) Foreign Application Priority Data
Aug. 8, 2023 (JP) 2023-129513

(51) Int. Cl. G03F 7/00

(52) U.S. Cl. CPC G03F 7/70066; G03F 7/70825

(57) ABSTRACT

A shutter device for passing and blocking light, includes a rotation source configured to rotationally drive a rotation shaft, a hub connected to the rotation shaft, and a shutter blade fixed to the hub. The hub includes a holding surface that holds the shutter blade, and the holding surface includes a first region belonging to a predetermined plane and a second region separated from the predetermined plane. The shutter blade contacts the first region and the second region while being fixed to the hub.

### BACKGROUND OF THE INVENTION

### Field of the Invention

The present invention relates to a shutter device, a lithography apparatus, and an article manufacturing method.

### Description of the Related Art

In a lithography method for manufacturing an article such as a semiconductor device, an exposure apparatus can be used to transfer a pattern of an original to a substrate. In the exposure apparatus, a shutter device can be used to control an exposure time or an exposure amount. The shutter device includes a shutter blade that blocks exposure light. A state in which exposure light is blocked by a shutter blade is a non-irradiation state in which a substrate is not irradiated with the exposure light and a state in which exposure light is not blocked by the shutter blade is an irradiation state in which the substrate is irradiated with the exposure light. The shutter device can switch between the non-irradiation state and the irradiation state by rotating the shutter blade by a rotation source. To improve the throughput of the exposure apparatus, it is necessary to improve the rotation speed of the shutter blade, and to do so the weight of the shutter blade can be reduced. However, if the weight of the shutter blade is reduced, the rigidity of the shutter blade may lower.

Japanese Patent Laid-Open No. 2008-141016 describes a shutter blade device in which a shutter blade is fixed to the rotation shaft of a motor while the shutter blade is sandwiched by a boss and a press plate. The shutter blade is fixed by bolts that are threaded into the boss and the press plate. The boss includes a first press member including two first pressing portions that press a first surface of the shutter blade. The press plate includes a second press member including a second pressing portion that presses a second surface of the shutter blade. When the second pressing portion is located at a position corresponding to a portion between the two first pressing portions, the shutter blade is deformed, thereby improving the rigidity of the shutter blade.

In the arrangement described in Japanese Patent Laid-Open No. 2008-141016, the first pressing portions and the second pressing portion for deforming the shutter blade are arranged at positions separated from the bolts. Therefore, a force that can be applied to the shutter blade by the first pressing portions and the second pressing portion is limited, and the deformation of the shutter blade and the improvement of the rigidity by the deformation can be restricted.

### SUMMARY OF THE INVENTION

The present invention provides a technique advantageous in improving the rigidity of a shutter blade.

One of aspects of the present invention provides a shutter device for passing and blocking light, comprising: a rotation source configured to rotationally drive a rotation shaft; a hub connected to the rotation shaft; and a shutter blade fixed to the hub, wherein the hub includes a holding surface that holds the shutter blade, and the holding surface includes a first region belonging to a predetermined plane and a second region separated from the predetermined plane, and the shutter blade contacts the first region and the second region while being fixed to the hub.

Further features of the present invention will become apparent from the following description of exemplary embodiments with reference to the attached drawings.

### BRIEF DESCRIPTION OF THE DRAWINGS

FIG. 1 is a view showing the arrangement of an exposure apparatus (lithography apparatus) according to an embodiment;

FIG. 2 is a view showing the arrangement of a shutter device according to the embodiment;

FIG. 3 is a view showing the structure of a hub according to the embodiment;

FIGS. 4A to 4C are views showing the arrangement of the shutter device according to the embodiment;

FIG. 5 is a view exaggeratedly showing a state in which a shutter blade is deformed;

FIG. 6 is a view showing the first modification;

FIG. 7 is a view showing the second modification;

FIG. 8 is a view showing the third modification;

FIG. 9 is a view showing the fourth modification;

FIG. 10 is a view showing the fifth modification;

FIG. 11 is a view showing the sixth modification; and

FIG. 12 is a view showing the seventh modification.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

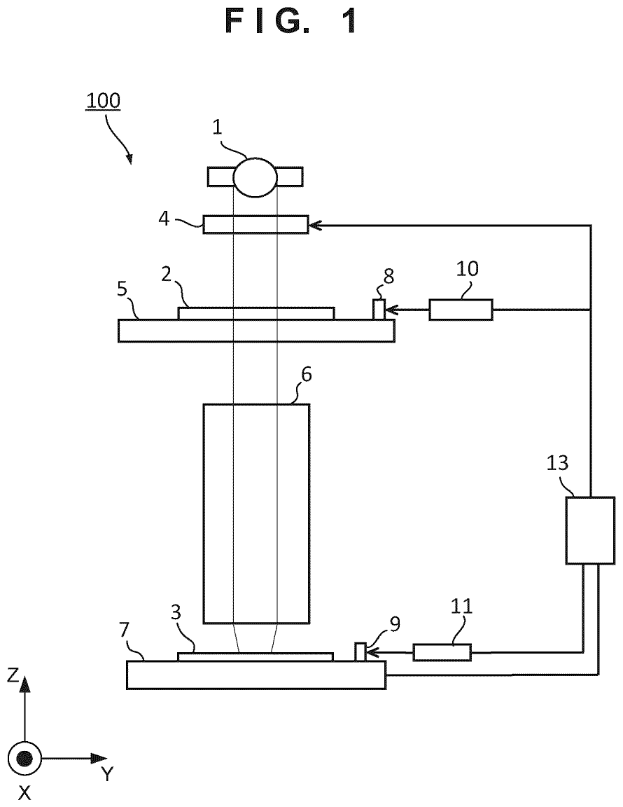

FIG. 1 shows the arrangement of an exposure apparatus 100 according to an embodiment. The exposure apparatus 100 is an example of a lithography apparatus that transfers a pattern of an original 2 to a substrate 3 using light. In addition to the exposure apparatus, an imprint apparatus is an example of the lithography apparatus.

The exposure apparatus 100 can include a light source 1, a shutter device 4, an original stage 5, a projection optical system 6, and a substrate stage 7. The exposure apparatus 100 can include a control unit 13 that controls the operation of the exposure apparatus 100. The exposure apparatus 100 may be formed as a scanner (scanning exposure apparatus) or a stepper. The light source 1 generates exposure light. As the light source 1, for example, a mercury lamp, a laser light source, or an EUV light source can be adopted.

The original stage 5 is positioned with respect to a two-dimensional direction parallel to a plane (that is, an X-Y plane) perpendicular to the optical axis (Z-axis) of the projection optical system 6 and a rotational direction (that is, a OZ direction) about the optical axis (Z-axis), thereby making it possible to position the original 2. The original stage 5 can be driven by a driving mechanism (not shown). A reflecting mirror 8 can be arranged on the original stage 5. A laser interferometer 10 can be arranged at a position facing the reflecting mirror 8. The laser interferometer 10 can measure, in real time, the rotation angle and the position of the original stage 5 in the two-dimensional direction, and provide the measurement result to the control unit 13. The control unit 13 can control the driving mechanism of the original stage 5 based on the measurement result from the laser interferometer 10, and position the original 2 held by the original stage 5.

The projection optical system 6 includes a plurality of optical elements, and projects the pattern of the original 2 onto the substrate 3 at a predetermined magnification. The substrate 3 is coated with a photosensitive agent (resist), and a latent image pattern is formed on the photosensitive agent when the pattern of the original 2 is projected onto the photosensitive agent. The substrate stage 7 can include, for example, a Z stage that holds the substrate 3, an X-Y stage that supports the Z stage, and a base that supports the X-Y stage. The substrate stage 7 can be driven by a driving mechanism such as a linear motor.

A reflecting mirror 9 can be arranged on the substrate stage 7. A laser interferometer 11 can be arranged at a position facing the reflecting mirror 9. The laser interferometer 11 can measure, in real time, the position of the substrate stage 7, and provide the measurement result to the control unit 13. The control unit 13 can control the driving mechanism of the substrate stage 7 based on the measurement result from the laser interferometer 11, and position the substrate 3 held by the substrate stage 7.

In a case where the exposure apparatus 100 is formed as a stepper, in an exposure process of exposing the substrate 3 in a state in which the substrate stage 7 is settled, the substrate 3 is irradiated with the exposure light generated by the light source 1. On the other hand, in a stepping phase of moving the substrate stage 7, the substrate 3 is not irradiated with the exposure light generated by the light source 1. The shutter device 4 is arranged between the light source 1 and the original stage 5, and passes or blocks the exposure light. The shutter device 4 passes the exposure light in the exposure process and blocks the exposure light in the stepping phase. The shutter device 4 is configured to switch irradiation/non-irradiation of the exposure light to the substrate 3, and the operation of the shutter device 4 is controlled by the control unit 13. The arrangement of the shutter device 4 will exemplarily be described below.

FIG. 2 is a view showing the arrangement of the shutter device 4 according to the embodiment. The shutter device 4 can include a rotation source 43 (for example, a motor) that rotationally drives or rotates a rotation shaft 44, a hub 42 connected to the rotation shaft 44, and a shutter blade 41 fixed to the hub 42. The shutter blade 41 includes a blocking portion 411 that blocks exposure light EL from the light source 1 and a passing portion 412 that passes the exposure light EL. In the example shown in FIG. 2, the shutter blade 41 includes three blocking portions 411 and three passing portions 412 but the number of blocking portions 411 and the number of passing portions 412 can arbitrarily be decided. When starting to expose the substrate 3, the control unit 13 rotates the shutter blade 41 to change a blocked state in which the blocking portion 411 blocks the exposure light EL to a non-blocked state in which the passing portion 412 passes the exposure light EL. On the other hand, when finishing exposing the substrate 3, the control unit 13 rotates the shutter blade 41 again to change the non-blocked state in which the passing portion 412 passes the exposure light EL to the blocked state in which the blocking portion 411 blocks the exposure light EL.

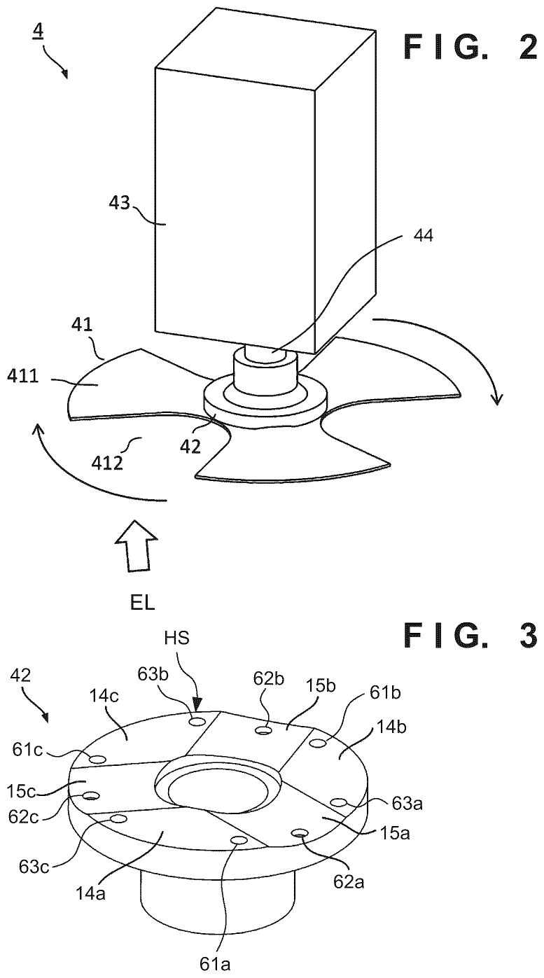

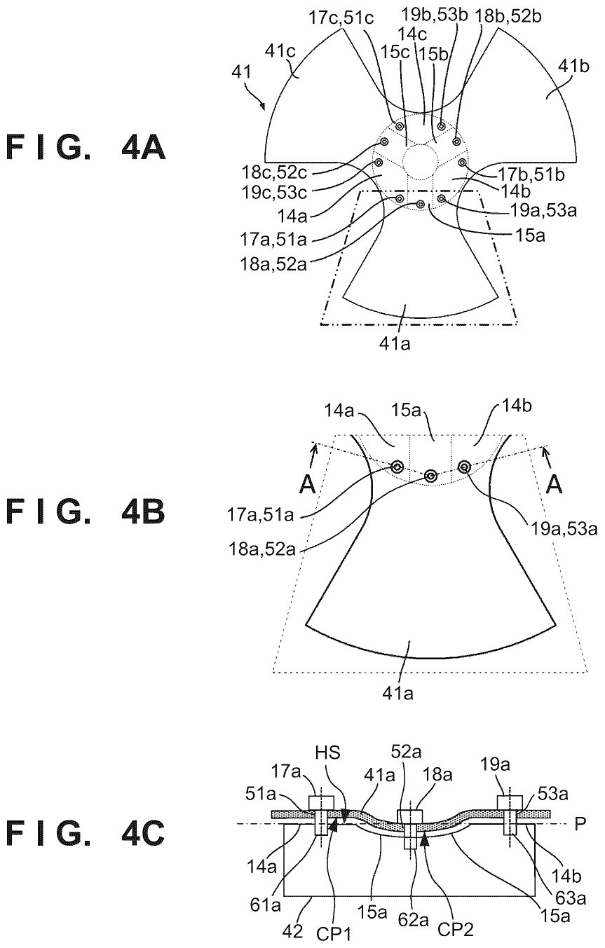

The structure of the hub 42 that holds the shutter blade 41 will exemplarily be described below. FIG. 3 exemplarily shows the structure of the hub 42 according to the embodiment. FIGS. 4A to 4C exemplarily show a state in which the shutter blade 41 is attached to the hub 42 according to the embodiment. FIG. 4A shows the whole shutter blade 41, FIG. 4B shows a part of the shutter blade 41, and FIG. 4C shows a section taken along a line A-A in FIG. 4B. Note that FIG. 4C shows a state in which a gap is provided between the hub 42 and the shutter blade 41 but the hub 42 and the shutter blade 41 can partially or wholly contact each other.

The shutter blade 41 can include at least one blade, and preferably include a plurality of blades 41a, 41b, and 41c. Each of the plurality of blades 41a, 41b, and 41c includes a region functioning as the above-described blocking portion 411. The hub 42 includes a holding surface HS that holds the shutter blade 41. The shutter blade 41 is fixed to the hub 42 by a plurality of fasteners 17a, 18a, 19a, 17b, 18b, 19b, 17c, 18c, and 19c. The shutter blade 41 can include a plurality of openings 51a, 52a, 53a, 51b, 52b, 53b, 51c, 52c, and 53c. The plurality of fasteners 17a, 18a, 19a, 17b, 18b, 19b, 17c, 18c, and 19c can include bolts extending through the openings, respectively. All or some of the plurality of fasteners 17a, 18a, 19a, 17b, 18b, 19b, 17c, 18c, and 19c may be formed by welding or adhesion. In a case where welding or adhesion is applied, an opening for a bolt is unnecessary. In a case where a bolt is used as a fastener, a toothed washer (lock washer) may be arranged between the shutter blade 41 and the seat surface of the bolt. A frictional force is increased by scratching the seat surface by the teeth of the toothed washer, and it is, therefore, possible to suppress the bolt from loosening.

The first aspect of the hub 42 will be described below. The holding surface HS of the hub 42 can include first regions 14a, 14b, and 14c that belong to the same plane (plane P). The holding surface HS can also include second regions 15a, 15b, and 15c that do not belong to the plane P to which the first regions 14a, 14b, and 14c belong. Each of the first regions 14a, 14b, and 14c can be formed by, for example, a flat surface (planar region) belonging to the plane P. The second regions 15a, 15b, and 15c are regions separated from the plane P. Each of the second regions 15a, 15b, and 15c can be formed by, for example, a curved surface.

The holding surface HS can include the first region 14a and the second region 15a that do not belong to the same plane (plane P). The holding surface HS can include the first region 14b and the second region 15b that do not belong to the same plane (plane P). The holding surface HS can include the first region 14c and the second region 15c that do not belong to the same plane (plane P). Examples of a form in which the first region and the second region that do not belong to the same plane are (1) a form in which the first region belongs to the plane P and the second region does not belong to the plane P and (2) a form in which the second region belongs to the plane and the first region does not belong to the plane P. Examples of a form in which a given region does not belong to the plane P are (1) a form in which the region belongs to a plane parallel to the plane P, (2) a form in which the region belongs to a plane intersecting the plane P, and (3) a form in which the region is formed by a curved surface. FIGS. 3 and 4A to 4C show an example in which each of the first regions 14a, 14b, and 14c is formed by a flat surface belonging to the plane P and each of the second regions 15a, 15b, and 15c is formed by a curved surface separated from the plane P.

The blade 41a of the shutter blade 41 is fixed to the hub 42 by the first fastener 17a in the first region 14a, and is fixed to the hub 42 by the second fastener 18a in the second region 15a. The blade 41b of the shutter blade 41 is fixed to the hub 42 by the first fastener 17b in the first region 14b, and is fixed to the hub 42 by the second fastener 18b in the second region 15b. The blade 41c of the shutter blade 41 is fixed to the hub 42 by the first fastener 17c in the first region 14c, and is fixed to the hub 42 by the second fastener 18c in the second region 15c. The shutter blade 41 can include a first contact portion CP1 that contacts the first regions 14a, 14b, and 14c and a second contact portion CP2 that contacts the second regions 15a, 15b, and 15c while being fixed to the hub 42. This arrangement is advantageous in improving the rigidity of the shutter blade 41 and reducing variations of assembly of the shutter device 4.

The shutter blade 41 includes the plurality of first openings 51a, 51b, and 51c and the plurality of second openings 52a, 52b, and 52c. The first fasteners 17a, 17b, and 17c can include first bolts that extend through the first openings 51a, 51b, and 51c and are fastened to screw holes 61a, 61b, and 61c of the hub 42, respectively. The second fasteners 18a, 18b, and 18c can include a plurality of second bolts that extend through the second openings 52a, 52b, and 52c and are fastened to screw holes 62a, 62b, and 62c of the hub 42, respectively.

As described above, the first regions 14a, 14b, and 14c and the second regions 15a, 15b, and 15c are arranged not to belong to the same plane (plane P). Therefore, when the blade 41a of the shutter blade 41 is fastened to the hub 42 by the first fastener 17a and second fastener 18a, it is deformed by a force (fastening force) received from the first fastener 17a, the second fastener 18a, and the hub 42. Similarly, when the blade 41b of the shutter blade 41 is fastened to the hub 42 by the first fastener 17b and second fastener 18b, it is deformed by a force received from the first fastener 17b, the second fastener 18b, and the hub 42. Similarly, when the blade 41c of the shutter blade 41 is fastened to the hub 42 by the first fastener 17c and second fastener 18c, it is deformed by a force received from the first fastener 17c, the second fastener 18c, and the hub 42. That is, the shutter blade 41 is forcibly deformed by being fixed to the hub 42 by the fasteners.

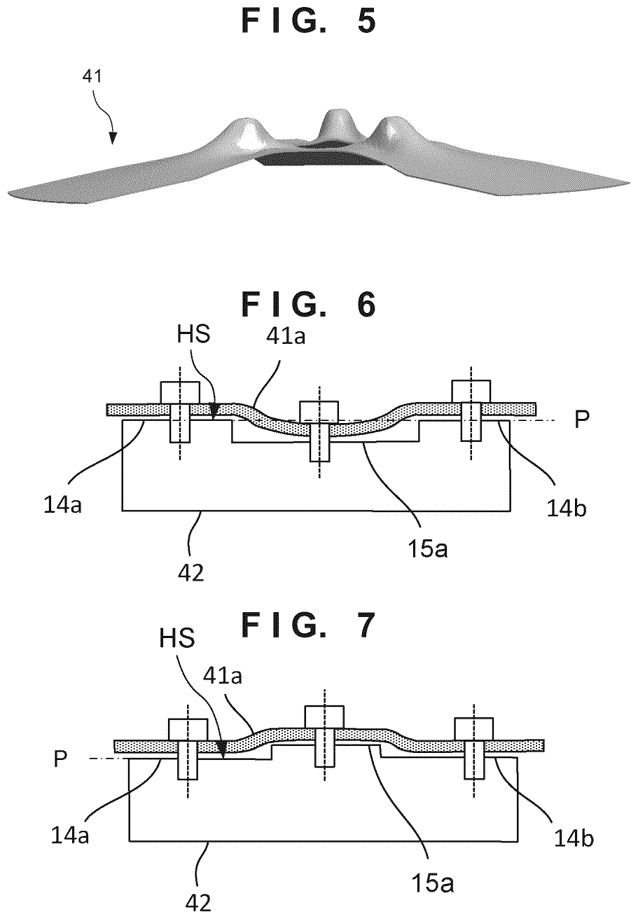

FIG. 5 exemplifies a state in which the shutter blade 41 is deformed. Note that FIG. 5 exaggeratedly shows the deformation of the shutter blade 41. When the shutter blade 41 is deformed by a force received from the fasteners 17a, 18a, 19a, 17b, 18b, 19b, 17c, 18c, and 19c and the hub 42, the second moment of area increases, as compared with a case where the shutter blade 41 is not deformed. This improves the rigidity of the shutter blade 41.

When creating a shutter blade having a curved shape exemplified in FIG. 5 by pressing or a 3D printer, it is difficult to perform mirror finishing for the shutter blade. On the other hand, according to this embodiment, the shutter blade 41 having a flat shape is created before being attached to the hub 42, and is then attached to the hub 42 to be deformed, thereby making it possible to improve the rigidity. Therefore, in this embodiment, it is easy to perform mirror finishing for the shutter blade 41. By performing mirror finishing for the shutter blade 41, it is possible to suppress the shutter blade 41 from absorbing the exposure light. This is advantageous in suppressing deformation and melting of the shutter blade 41 by heat.

It may be understood that the hub 42 has the second aspect to be described below. According to the second aspect, the holding surface HS includes the first region 14a, the second region 15a, and the third region 14b. The second region 15a is arranged between the first region 14a and the third region 14b, the first region 14a and the third region 14b belong to a virtual plane (plane P), and the second region 15a does not belong to the virtual plane (plane P). The shutter blade 41 is fixed to the hub 42 by the third fastener 19a in the third region 14b. The second region 15a can be formed by a curved surface. Alternatively, the second region 15a may be formed by a flat surface parallel to the virtual plane (plane P). For example, the second region 15a is recessed with respect to the first region 14a and the third region 14b. The shutter blade 41 includes the plurality of third openings 53a, 53b, and 53c. The third fasteners 19a, 19b, and 19c can include first bolts that extend through the plurality of third openings 53a, 53b, and 53c, respectively. The third fasteners 19a, 19b, and 19c can include third bolts that extend through the third openings 53a, 53b, and 53c and are fastened to screw holes 63a, 63b, and 63c of the hub 42, respectively.

Modifications of the above-described embodiment will be described below. Matters not mentioned in the following description can comply with the above-described embodiment.

FIG. 6 shows the first modification. FIG. 6 corresponds to the section taken along the line A-A in FIG. 4B. As exemplified in FIG. 6, the first region 14a of the holding surface HS of the hub 42 can be formed by a first flat surface that belongs to the virtual plane (plane P), and the second region 15a of the holding surface HS can be formed by a second flat surface that does not belong to the virtual plane to which the first flat surface belongs. The second flat surface may or may not be parallel to the first flat surface. In another aspect, the holding surface HS includes the first region 14a, the second region 15a, and the third region 14b. The second region 15a is arranged between the first region 14a and the third region 14b, the first region 14a and the third region 14b belong to the virtual plane (plane P), and the second region 15a is formed by the second flat surface that does not belong to the virtual plane (plane P). The second region 15a is recessed with respect to the first region 14a and the third region 14b.

FIG. 7 shows the second modification. FIG. 7 corresponds to the section taken along the line A-A in FIG. 4B. As exemplified in FIG. 7, the first region 14a of the holding surface HS of the hub 42 is formed by the first flat surface that belongs to the virtual plane (plane P), and the second region 15a of the holding surface HS is formed by the second flat surface that does not belong to the virtual plane to which the first flat surface belongs. The second flat surface may or may not be parallel to the first flat surface. In another aspect, the holding surface HS includes the first region 14a, the second region 15a, and the third region 14b. The second region 15a is arranged between the first region 14a and the third region 14b. The holding surface HS can have a convex shape formed by the first region 14a, the second region 15a, and the third region 14b.

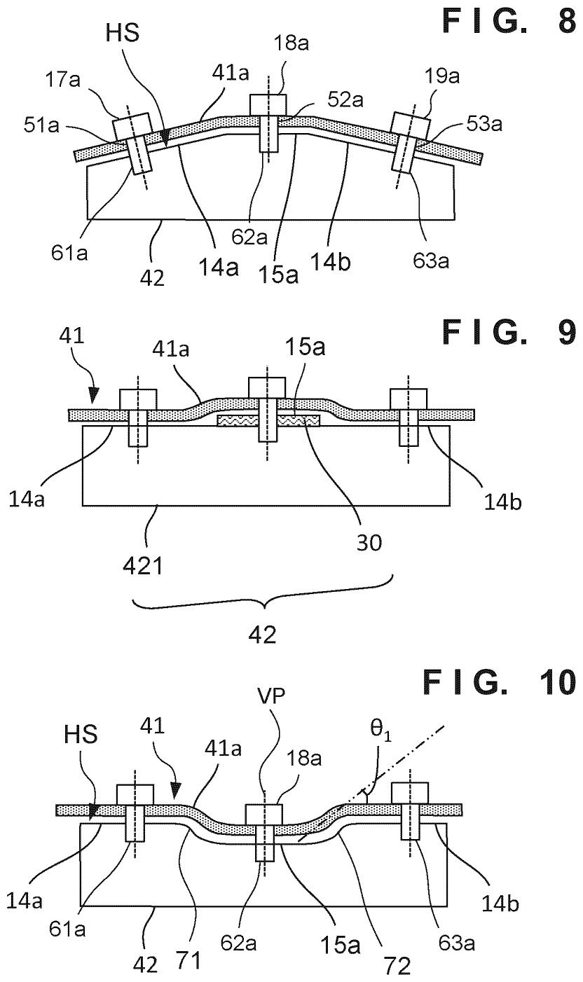

FIG. 8 shows the third modification. FIG. 8 corresponds to the section taken along the line A-A in FIG. 4B. As exemplified in FIG. 8, the holding surface HS includes the first region 14a, the second region 15a, and the third region 14b. The second region 15a is arranged between the first region 14a and the third region 14b. The first region 14a, the second region 15a, and the third region 14b can be formed by flat surfaces that are not parallel to each other. The holding surface HS can have a convex shape formed by the first region 14a, the second region 15a, and the third region 14b. The first region 14a and the third region 14b can be inclined regions.

FIG. 9 shows the fourth modification. FIG. 9 corresponds to the section taken along the line A-A in FIG. 4B. The hub 42 can include a base 421 connected to the rotation shaft 44, and a spacer 30 arranged between the base 421 and the shutter blade 41. The surface of the base 421 includes the first region 14a (and the third region 14b), and the surface of the spacer 30 includes the second region 15a. By forming the hub 42 by the base 421 and the spacer 30 in this way, it can be easy to create the hub 42.

FIG. 10 shows the fifth modification. FIG. 10 corresponds to the section taken along the line A-A in FIG. 4B. The holding surface HS of the shutter blade 41 can include a curved surface 71 that connects the first region 14a and the second region 15a. In addition, the holding surface HS can include a curved surface 72 that connects the second region 15a and the third region 14b. This arrangement is advantageous in relaxing a stress applied to the shutter blade 41 by the boundary portion between the first region 14a and the second region 15a and/or the boundary portion between the second region 15a and the third region 14b. This can contribute to improvement of the durability of the shutter blade 41 or the shutter device 4. At least portions, where the screw holes 61a, 61b, and 61c are formed, of the first region 14a, the second region 15a, and the third region 14b are preferably flat. This arrangement is also advantageous in relaxing a stress applied to the shutter blade 41.

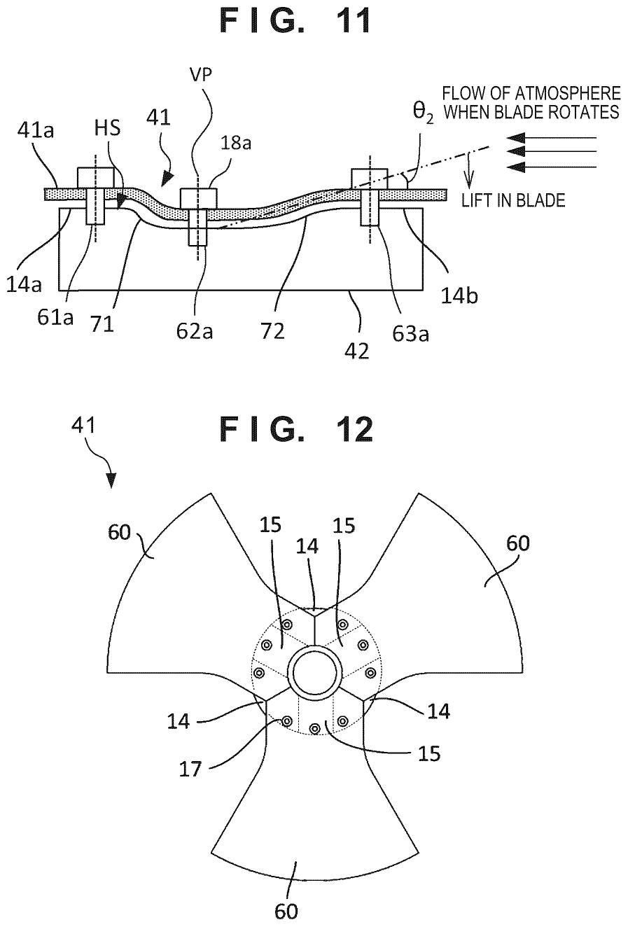

FIG. 11 shows the sixth modification. FIG. 11 corresponds to the section taken along the line A-A in FIG. 4B. The sixth modification is a modification of the fifth modification. The holding surface HS of the shutter blade 41 can have a shape asymmetrical with respect to a virtual plane VP including the central axis of the rotation shaft 44 and the center of the second fastener 18a. The fifth modification shown in FIG. 10 may be understood as an example in which the holding surface HS of the shutter blade 41 has a shape symmetrical with respect to the virtual plane VP including the central axis of the rotation shaft 44 and the center of the second fastener 18a. In the fifth modification shown in FIG. 10, the inclination angle (the inclination angle with respect to a plane perpendicular to the virtual plane VP and the rotation shaft 44) of the portion of the shutter blade 41, which covers the curved surface 72 of the holding surface HS of the hub 42, is θ1. In the sixth modification shown in FIG. 11, the inclination angle (the inclination angle with respect to a plane perpendicular to the virtual plane VP and the rotation shaft 44) of the portion of the shutter blade 41, which covers the curved surface 72 of the holding surface HS of the hub 42, is θ2, and θ2<θ1 holds. The air resistance at the time of rotation of the shutter blade 41 of the fifth modification is relaxed, as compared with the shutter blade 41 of the fourth modification, thereby reducing lift acting at the time of rotation.

FIG. 12 shows the seventh modification. In the seventh modification, the shutter blade 41 is formed from a plurality of members, and each member includes one blade 60. That is, the shutter blade 41 can include a plurality of blades 60 that be divided and separated from each other when fastening by the bolts 17 is released. The hub 42 includes a flat surface 14 and a curved surface 15, and each blade 60 is fastened to the flat surface 14 and the curved surface 15 by the bolts 17 and is then deformed. When the shutter blade 41 is formed from the plurality of members, it is possible to reduce the process cost.

An article manufacturing method of manufacturing an article using a lithography apparatus represented by the exposure apparatus 100 will be described below. The article can be, for example, a semiconductor IC element, a liquid crystal display element, a MEMS, or the like. The article manufacturing method can include a transfer step of transferring a pattern of an original to a substrate using the lithography apparatus, and a processing step of obtaining an article by processing the substrate having undergone the transfer step. When the lithography apparatus is an exposure apparatus, the transfer step can include an exposure step of exposing a substrate (a wafer, a glass substrate, or the like) coated with a photosensitive agent, and a step of developing the substrate (photosensitive agent) having undergone the exposure step. When the lithography apparatus is an imprint apparatus, the transfer step can include a contact step of bringing the original into contact with an imprint material on the substrate, a curing step of curing the imprint material, and a separation step of separating the original from the cured imprint material. The processing step can include, for example, etching, resist removal, dicing, bonding, and packaging.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-129513, filed Aug. 8, 2023 which is hereby incorporated by reference herein in its entirety.

What is claimed is:

1. A shutter device for passing and blocking light, comprising:
a rotation source configured to rotationally drive a rotation shaft;
a hub connected to the rotation shaft; and
a shutter blade fixed to the hub,
wherein the hub includes a holding surface that holds the shutter blade, and the holding surface includes a first region belonging to a predetermined plane and a second region separated from the predetermined plane, and
the shutter blade contacts the first region and the second region while being fixed to the hub.

2. The shutter device according to claim 1, wherein the shutter blade is fastened to the hub by a first fastener in the first region, and is fastened to the hub by a second fastener in the second region.

3. The shutter device according to claim 2, wherein
the shutter blade includes a first opening and a second opening, and
the first fastener includes a first bolt that extends through the first opening, and the second fastener includes a second bolt that extends through the second opening.

4. The shutter device according to claim 2, wherein the shutter blade is deformed by a force receiving from the first fastener, the second fastener, and the hub.

5. The shutter device according to claim 1, wherein the shutter blade includes a contact portion that contacts the first region and a contact portion that contacts the second region while being fixed to the hub.

6. The shutter device according to claim 1, wherein the first region of the holding surface is formed by a flat surface, and the second region of the holding surface is formed by a curved surface.

7. The shutter device according to claim 1, wherein the first region is formed by a first flat surface, and the second region is formed by a second flat surface that does not belong to a virtual plane to which the first flat surface belongs.

8. The shutter device according to claim 1, wherein
the holding surface further includes a third region,
the second region is arranged between the first region and the third region,
the first region and the third region belong to a virtual plane,
the second region does not belong to the virtual plane, and
the shutter blade is fixed to the hub by a third fastener in the third region.

9. The shutter device according to claim 8, wherein the second region is formed by a curved surface.

10. The shutter device according to claim 8, wherein the second region is formed by a flat surface parallel to the virtual plane.

11. The shutter device according to claim 8, wherein the second region is recessed with respect to the first region and the third region.

12. The shutter device according to claim 11, wherein the holding surface includes a curved surface that connects the first region and the second region, and a curved surface that connects the second region and the third region.

13. The shutter device according to claim 12, wherein the holding surface has a shape asymmetrical with respect to a virtual plane including a central axis of the rotation shaft and a center of a second fastener that fastens the shutter blade to the hub in the second region.

14. The shutter device according to claim 8, wherein the first region, the second region, and the third region form a convex shape.

15. The shutter device according to claim 1, wherein
the holding surface further includes a third region,
the second region is arranged between the first region and the third region,
the first region, the second region, and the third region are formed by flat surfaces that are not parallel to each other, and
the shutter blade is fixed to the hub by a third fastener in the third region.

16. The shutter device according to claim 15, wherein the holding surface has a convex shape formed by the first region, the second region, and the third region.

17. The shutter device according to claim 1, wherein
the hub includes a base connected to the rotation shaft, and a spacer arranged between the base and the shutter blade, and
the surface of the base includes the first region, and the surface of the spacer includes the second region.

18. The shutter device according to claim 1, wherein the shutter blade is formed from a plurality of members.

19. A lithography apparatus for transferring a pattern of an original to a substrate using light, comprising:
a shutter device defined in claim 1 and arranged to control irradiation of the light to the substrate.

20. An article manufacturing method comprising:
transferring a pattern of an original to a substrate using a lithography apparatus defined in claim 19; and
processing the substrate having undergone the transferring to obtain an article.
